(19) United States
(12) Patent Application Publication
(10) Pub. No.: US 2014/0168558 A1
(43) Pub. Date: Jun. 19, 2014

(54) TFT ARRAY SUBSTRATE AND LIQUID CRYSTAL DISPLAY

(71) Applicant: BEIJING BOE OPTOELECTRONICS TECHNOLOGY CO., LTD., Beijing (CN)

(72) Inventors: WENSEN SHI, Beijing (CN); XIN LI, Beijing (CN); JIAN REN, Beijing (CN)

(73) Assignee: BEIJING BOE OPTOELECTRONICS TECHNOLOGY CO., LTD., Beijing (CN)

(21) Appl. No.: 14/108,610

(22) Filed: Dec. 17, 2013

(30) Foreign Application Priority Data
Dec. 19, 2012 (CN) 201220707201.1

(51) Int. Cl. G02F 1/1362; H01L 27/12

(52) U.S. Cl. CPC G02F 1/13624; H01L 27/124
USPC 349/43; 257/72

(57) ABSTRACT

There are provided a TFT array substrate and a liquid crystal display. The TFT array substrate includes: a substrate with a peripheral wiring area set on it; a transparent conductive layer disposed in the peripheral wiring area, which includes a plurality of first conductive layer areas and a plurality of second conductive layer areas; and a protective layer disposed under the plurality of first conductive layer areas. A top surface of the conductive layer in the plurality of first conductive layer areas is located in the same plane in parallel with the substrate.

### FIELD OF THE INVENTION

Embodiments of the present invention relate to a Thin Film Transistor (TFT) array substrate and a liquid crystal display.

### BACKGROUND

For a Thin Film Transistor-Liquid Crystal Display (TFT-LCD), the degree of rotation of liquid crystal molecules is changed by utilizing a variance in the electric field intensity applied on a liquid crystal layer, so that the light transmission level is controlled to display an image.

With the decrease in size of the liquid crystal display, wirings in a peripheral area of a TFT array substrate will be subject to the limitation of space accordingly. Two kinds of metal wiring structures are gradually adopted in the manufacture of TFT array substrates, so that spacing between metal lines can be decreased, and then, the space is fully utilized, and the structure of products is optimized.

However, when the two kinds of metal wiring structures are used, in a four-mask (4 mask) process, because a step exists between different metal layers, difference of the contact resistance may happen to a pad area of an integrated chip (IC) and the TFT array substrate. For details, reference to FIG. 1 can be made. In FIG. 1, upon bonding of a TFT array substrate 1 and an IC 2, as the pad area employs different metal layers (e.g. a Gate metal layer 4 and a source and drain (SD) metal layer 5 shown in FIG. 1), a transparent electrode located on the surface (schematically shown by indium tin oxide (ITO) 9 in FIG. 1) is not in the same height. In this case, when the IC 2 and the TFT array substrate are subjected to bonding, the degree of pressing of conductive adhesive particles on the Gate metal layer 4 and the SD metal layer 5 differs, and the final bonding results will also be different. Then, this brings about difference of the contact resistance, leading to difference in transmission of driving signals and occurrence of display bright-lines.

### SUMMARY

According to an embodiment of the invention, there is provided a thin film transistor (TFT) array substrate, comprising: a substrate with a peripheral wiring area set on it; a transparent conductive layer disposed in the peripheral wiring area, which includes a plurality of first conductive layer areas and a plurality of second conductive layer areas; and a protective layer disposed under the plurality of first conductive layer areas, wherein a top surface of the conductive layer in the plurality of first conductive layer areas is located in a same plane in parallel with the substrate.

In an example, the protective layer is set to be different thicknesses at locations corresponding to the plurality of first conductive layer areas, so that top surfaces of conductive layers in the plurality of first conductive layer areas are located in the same plane in parallel with the substrate.

In an example, the array substrate further includes a gate metal layer and a gate protective layer formed on the gate metal layer, the protective layer includes a first protective layer area that is disposed on a data metal layer and a second protective layer area that is disposed on the gate protective layer, and thickness of the protective layer in the first protective layer area is smaller than thickness of the protective layer in the second protective layer area.

In an example, the array substrate further includes a semiconductor layer that is formed on the gate protective layer and located under the data metal layer.

In an example, the difference of thickness between the protective layer in the first protective layer area and the protective layer in the second protective layer area is a difference between a sum of thickness of the data metal layer and the semiconductor layer and thickness of the gate metal layer.

In an example, in a region corresponding to the first conductive layer area, the gate protective layer, the semiconductor layer, the data metal layer, the protective layer and the transparent conductive layer are laminated in sequence from the substrate side; and in a region corresponding to the second conductive area, the gate metal layer, the gate protective layer, the protective layer and the transparent conductive layer are laminated in sequence from the substrate side.

According to an embodiment of the invention, there is further provided a liquid crystal display, comprising the array substrate as stated above.

In an example, the liquid crystal display further includes an IC circuit board, which is connected to the array substrate through a conductive adhesive.

In an example, the conductive adhesive contains conductive gold balls.

According to the invention, by means of adjusting thickness of the protective layer, the top surface of the transparent conductive layer located in the first conductive layer area for the peripheral wiring area of the TFT array substrate is made to be situated in the same plane in parallel with the substrate, so as to decrease a step region due to the thickness problem. Thus, occurrence of the poorness of product as a result of the step is reduced, and yield is enhanced.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a schematically sectional view illustrating the structure of an existing liquid crystal panel after it is connected to an IC circuit board;

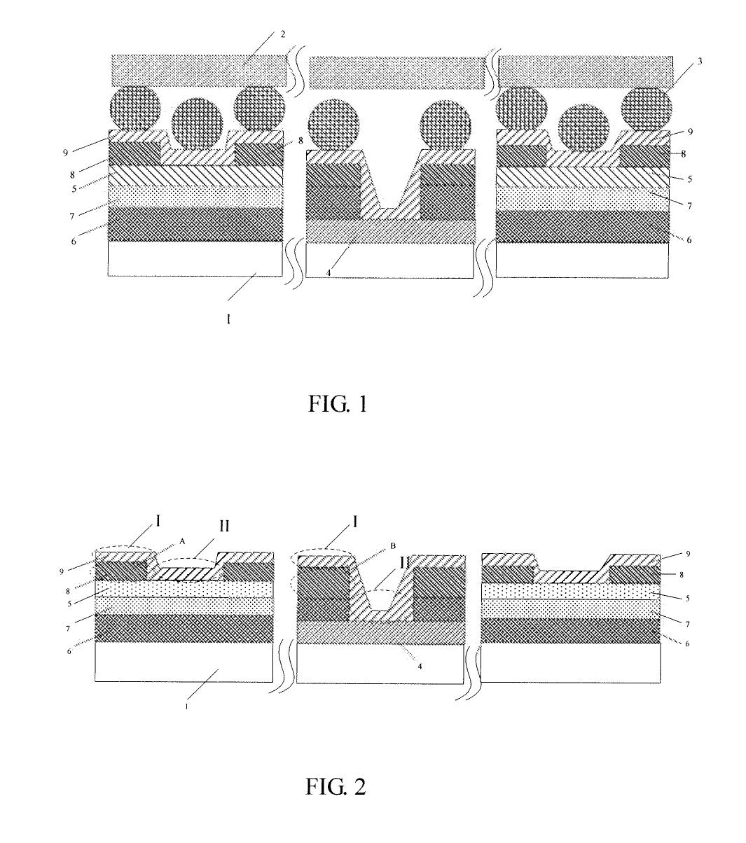

FIG. 2 is a schematically sectional view illustrating the structure of a TFT array substrate provided by the invention;

FIG. 3 is a schematically sectional view illustrating the structure of a liquid crystal panel provided by the invention after it is connected to an IC circuit board;

FIGS. 4 to 8 are flow charts illustrating a process for forming a protective layer with different thicknesses.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

According to an embodiment of the invention, there is provided a TFT array substrate, which includes a substrate with a peripheral wiring area disposed thereon, a transparent conductive layer which includes a first conductive layer area and a second conductive layer area being disposed in the peripheral wiring area, a protective layer being disposed under the first conductive layer area, and a top surface of the conductive layer in the first conductive layer area being located in the same plane in parallel with the substrate.

The array substrate further includes a gate metal layer and a gate insulating layer formed on the gate metal layer, the protective layer includes a first protective layer area that is disposed on a data metal layer and a second protective layer area that is disposed on a gate protective layer, and thickness of the protective layer in the first protective layer area is smaller than thickness of the protective layer in the second protective layer area.

Further, the array substrate further includes a semiconductor layer that is formed on the gate insulating layer and located under the data metal layer.

The difference of thickness between the protective layer in the first protective layer area and the protective layer in the second protective layer area is a difference between a sum of thickness of the data metal layer and the semiconductor layer and thickness of the gate metal layer.

According to an embodiment of the invention, there is further provided a liquid crystal display, comprising the array substrate as stated above.

Further, the liquid crystal display further includes an IC circuit board, which is connected to the array substrate through a conductive adhesive. For example, the IC circuit board is connected to the peripheral wiring area of the array substrate.

The conductive adhesive contains conductive gold balls.

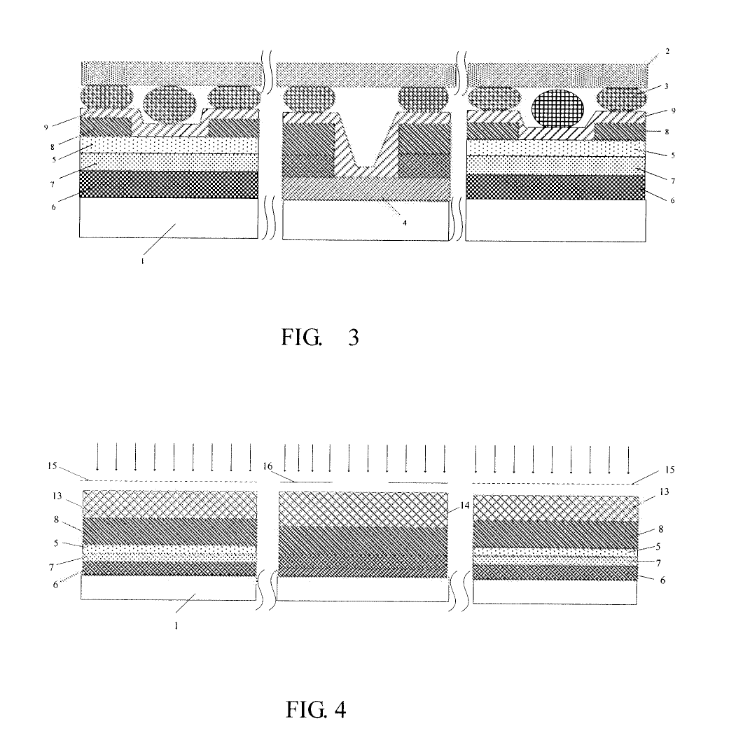

Hereinafter, the array substrate will be specifically described in combination with a concrete embodiment, and FIG. 2 shows the sectional structure of a peripheral wiring area of a TFT array substrate according to the invention. As shown in FIG. 2, a transparent conductive layer 9 that includes a first conductive layer area I and a second conductive layer area II is provided in the peripheral wiring area, a protective layer 8 is provided under the first conductive area 1, and a top surface of the conductive layer in the first conductive layer area is located in the same plane in parallel with the substrate 1.

For example, the protective layer 8 includes a first protective layer area A and a second protective layer area B, and thickness of the protective layer in the first protective layer area A is smaller than thickness of the protective layer in the second protective layer area B. The first protective layer area A is disposed on a data metal layer 5, and the second protective layer area B is disposed on a gate protective layer 6.

For example, the array substrate further includes a semiconductor layer 7 formed under the data metal layer 5.

For example, the difference of thickness between the protective layer in the first protective layer area A and the protective layer in the second protective layer area B is a difference between a sum of thickness of the data metal layer 5 and the semiconductor layer 7 and thickness of a gate metal layer 4.

Here, in order to ensure that the conductive layer positioned in the first conductive layer area is located in the same plane in parallel with the substrate, it is necessary to make sure that thickness of the protective layer in the first protective layer area is a sum of thickness of the protective layer in the second protective layer area and thickness of the semiconductor layer. As such, in the manufacturing process of the TFT array substrate 1, it is possible that when a via mask process is performed, a half-tone mask process is conducted on the peripheral wiring area to adjust thickness of the protective layer in the second protective layer area B, so that a sum of thickness of the protective layer in the first protective layer area A and thickness of the semiconductor layer 7 is thickness of the protective layer in the second protective layer area B.

Further, the gate metal layer 4 and the data metal layer 5 have the same thickness. For example, it may range between 1800 Å and 3000 Å, and for example, 2200 Å is employed for it.

For example, 4000 Å is normally employed for the gate protective layer, and 2300 Å is normally employed for the semiconductor layer. In this case, thickness of the protective layer in the first protective layer area A may be set as 2500 Å, and thickness of the protective layer in the second protective layer area B may be set as 4800 Å, so as to ensure that after the transparent conductive layer is deposited, a top surface of the conductive layer in the first conductive layer area is located in the same plane in parallel with the substrate.

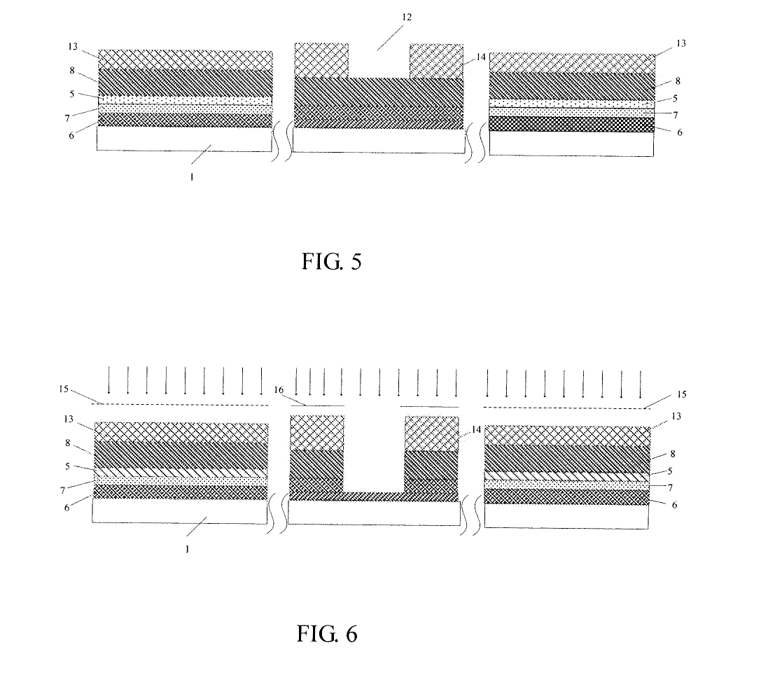

FIG. 3 is a cross-sectional view illustrating a panel after an IC driving plate is connected to the substrate. As can be seen from the drawing, by the improvement in the structure, such a region that a step exists therein is reduced, and thus yield of products is increased.

According to the invention, by means of adjusting thickness of the protective layer, the top surface of the transparent conductive layer located in the first conductive layer area for the peripheral wiring area of the TFT array substrate is made to be situated in the same plane in parallel with the substrate, so as to decrease a step region due to the thickness problem. Thus, occurrence of the poorness of product as a result of the step is reduced, and yield is enhanced.

In order to illustrate the adjustment process by the half-tone mask process further, a more detailed description will be given below in conjunction with FIGS. 3 to 8.

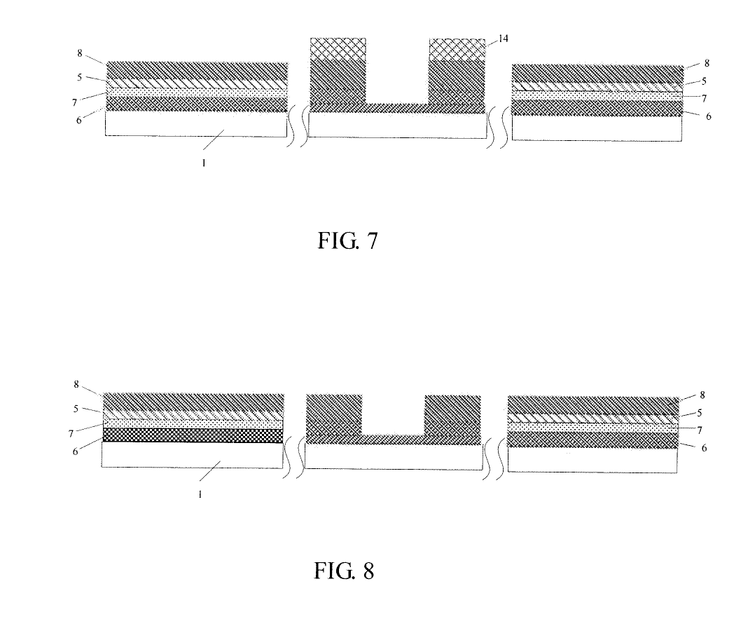

FIG. 4 shows the sectional structure of the substrate upon via mask in the course of forming the TFT array substrate shown in FIG. 2. For example, after deposition of a Gate metal layer, photolithography, etching and other processes are conducted on a glass substrate, a desired gate metal layer 4 is formed. Afterwards, a gate protective layer, a semiconductor layer, a data metal layer and a protective layer are deposited sequentially by using a plasma enhanced chemical vapor deposition (PECVD) method, and photoresist is applied on the protective layer, so that a photoresist retained region, a photoresist removed region, and a photoresist partially-retained region are obtained through a half-tone mask process. An etch process is performed on the photoresist removed region to etch off the protective layer in the photoresist removed region, so that a desired via is formed. After that, ashing is performed to remove the photoresist in the partially-retained region, and the exposed protective layer is etched. Afterwards, the photoresist in the retained region is removed, so as to form the protective layer with difference thicknesses. For example, in the above process, thickness of the coated photoresist may be set as 18000 Å, and after exposure, thickness of the photoresist retained region is 18000 Å, thickness of the photoresist partially-retained region is 5000 Å, and the photoresist removed region is fully removed.

The array substrate after the photoresist is applied on it is shown in FIG. 4, and thickness of the coated photoresist may be set as 18000 Å.

FIG. 5 is a schematic view illustrating the array substrate subjected to the half-tone mask process. For example, the substrate with the photoresist coated thereon is subjected to exposure with a half-tone mask 15, so as to form a photoresist retained region 14, a photoresist removed region 12 and a photoresist partially-retained region 13, and the protective layer and the gate protective layer in the photoresist removed region are etched, so as to form a desired via. The resultant structure is shown in FIG. 6.

An ashing process is conducted on the partially-retained region of photoresist in FIG. 6 to remove the photoresist in the partially-retained region 13, and the exposed protective layer is etched to retain a desired thickness, so that a first protective layer area is formed. For example, thickness of the protective layer may be 2500 Å, and the resultant structure is shown in FIG. 7.

The remaining photoresist on the array substrate shown in FIG. 7 is removed, so as to form a protective layer with different thicknesses as shown in FIG. 8.

It is to be noted that, if what is employed for the protective layer is a photosensitive resin material, then exposure, development and other processes can be conducted with a half-tone mask directly, without the necessity of coating photoresist. This is a technology well-known by those skilled in the art, and details are omitted here.

The description has been given above to the example in which in a region corresponding to the first conductive layer area, the gate protective layer, the semiconductor layer, the data metal layer, the protective layer and the transparent conductive layer are laminated in sequence from the substrate side; in a region corresponding to the second conductive area, the gate metal layer, the gate protective layer, the protective layer and the transparent conductive layer are laminated in sequence from the substrate side. However, embodiments of the invention are not limited thereto. The peripheral wiring area may include other layer(s) than the above layers. In embodiments of the invention, the top surface of the conductive layer in a plurality of first conductive layer areas can be made to be located in the same plane in parallel with the substrate by means of adjusting thickness of the protective layer.

The foregoing is merely exemplary embodiments of the invention, but is not used to limit the protection scope of the invention. The protection scope of the invention shall be defined by the attached claims.

What is claimed is:

1. A thin film transistor (TFT) array substrate, comprising:
a substrate with a peripheral wiring area set on it;
a transparent conductive layer disposed in the peripheral wiring area, which includes a plurality of first conductive layer areas and a plurality of second conductive layer areas; and
a protective layer disposed under the plurality of first conductive layer areas, wherein a top surface of the conductive layer in the plurality of first conductive layer areas is located in a same plane in parallel with the substrate.

2. The TFT array substrate according to claim 1, wherein, the protective layer is set to be different thicknesses at locations corresponding to the plurality of first conductive layer areas, so that the top surface of the conductive layer in the plurality of first conductive layer areas is located in the same plane in parallel with the substrate.

3. The TFT array substrate according to claim 1, wherein, the array substrate further includes a gate metal layer and a gate protective layer formed on the gate metal layer, the protective layer includes a first protective layer area that is disposed on a data metal layer and a second protective layer area that is disposed on the gate protective layer, and thickness of the protective layer in the first protective layer area is smaller than thickness of the protective layer in the second protective layer area.

4. The TFT array substrate according to claim 3, wherein, the array substrate further includes a semiconductor layer that is formed on the gate protective layer and located under the data metal layer.

5. The TFT array substrate according to claim 4, wherein, the difference of thickness between the protective layer in the first protective layer area and the protective layer in the second protective layer area is a difference between a sum of thickness of the data metal layer and the semiconductor layer and thickness of the gate metal layer.

6. The TFT array substrate according to claim 5, wherein, in a region corresponding to the first conductive layer area, the gate protective layer, the semiconductor layer, the data metal layer, the protective layer and the transparent conductive layer are laminated in sequence from the substrate side; and in a region corresponding to the second conductive area, the gate metal layer, the gate protective layer, the protective layer and the transparent conductive layer are laminated in sequence from the substrate side.

7. A liquid crystal display that includes an array substrate, the array substrate comprising:
a substrate with a peripheral wiring area set on it;
a transparent conductive layer disposed in the peripheral wiring area, which includes a plurality of first conductive layer areas and a plurality of second conductive layer areas; and
a protective layer disposed under the plurality of first conductive layer areas, wherein a top surface of the conductive layer in the plurality of first conductive layer areas is located in a same plane in parallel with the substrate.

8. The liquid crystal display according to claim 7, further comprising an IC circuit board, which is connected to the peripheral wiring area of the array substrate through a conductive adhesive.

9. The liquid crystal display according to claim 8, wherein, the conductive adhesive contains conductive gold balls.

10. The liquid crystal display according to claim 7, wherein, the protective layer is set to be different thicknesses at locations corresponding to the plurality of first conductive layer areas, so that the top surface of the conductive layer in the plurality of first conductive layer areas is located in the same plane in parallel with the substrate.

11. The liquid crystal display according to claim 7, wherein, the array substrate further includes a gate metal layer and a gate protective layer formed on the gate metal layer, the protective layer includes a first protective layer area that is disposed on a data metal layer and a second protective layer area that is disposed on the gate protective layer, and thickness of the protective layer in the first protective layer area is smaller than thickness of the protective layer in the second protective layer area.

12. The liquid crystal display according to claim 11, wherein, the array substrate further includes a semiconductor layer that is formed on the gate protective layer and located under the data metal layer.

13. The liquid crystal display according to claim 12, wherein, the difference of thickness between the protective layer in the first protective layer area and the protective layer in the second protective layer area is a difference between a sum of thickness of the data metal layer and the semiconductor layer and thickness of the gate metal layer.

14. The liquid crystal display according to claim 13, wherein, in a region corresponding to the first conductive layer area, the gate protective layer, the semiconductor layer, the data metal layer, the protective layer and the transparent conductive layer are laminated in sequence from the substrate side; and in a region corresponding to the second conductive area, the gate metal layer, the gate protective layer, the protective layer and the transparent conductive layer are laminated in sequence from the substrate side.
